(19) United States
(12) Patent Application Publication
(10) Pub. No.: US 2026/0090141 A1
(43) Pub. Date: Mar. 26, 2026

(54) LIGHT-EMITTING DIODE, LIGHT-EMITTING DIODE ARRAY AND METHOD OF MANUFACTURING A LIGHT-EMITTING DIODE DIE

(71) Applicant: Lumileds LLC, San Jose, CA (US)

(72) Inventor: Brendan J. Moran, San Jose, CA (US)

(73) Assignee: Lumileds LLC, San Jose, CA (US)

(21) Appl. No.: 19/113,526

(22) PCT Filed: Nov. 9, 2023
(86) PCT No.: PCT/US2023/037051

§ 371 Date: Mar. 20, 2025

Related U.S. Application Data
(60) Provisional application No. 63/384,247, filed on Nov. 18, 2022.

(51) Int. Cl. H10H 20/813; H01L 25/075; H10H 20/01; H10H 20/811; H10H 20/825; H10H 20/851; H10H 29/24

(52) U.S. Cl. CPC H10H 20/8131; H10H 20/01335; H10H 20/0361; H10H 20/811; H10H 20/825; H10H 20/8512; H10H 29/24; H10W 90/00

(57) ABSTRACT

Provided is an LED (100) comprised of an epitaxial stack having two active regions (106a, 106b) separated by a tunnel junction (108). A red converting element (112) may be added selectively to pixels during device isolation/processing to create an array of pixels that can be controlled to be blue or green or a mix of the two, and other pixels that use the blue or green active regions to pump the red converting element (112) to stimulate red emission from this specific pixel area. An alternative can be during device processing to selectively remove the topmost active region (green or blue) and replace that with a red converting material. This could permit a coplanar final structure.

### TECHNICAL FIELD

Embodiments of the disclosure generally relate to arrays of light emitting diode (LED) devices and methods of manufacturing the same. More particularly, embodiments are directed to light emitting diode devices having no red light emitting active region, and instead having a patternable light conversion layer to emit red light.

### BACKGROUND

A light emitting diode (LED) is a semiconductor light source that emits visible light when current flows through it. LEDs combine a P-type semiconductor with an N-type semiconductor. LEDs commonly use a III-group compound semiconductor. A III-group compound semiconductor provides stable operation at a higher temperature than devices that use other semiconductors. The III-group compound is typically formed on a substrate formed of sapphire or silicon carbide (SiC).

The concept of a three quantum well stack enabling a full display gamut from a single geometric pixel area is compelling, practically, however, accessing a stack of three p-n junctions and ensuring that each is optimized to perform and also be produced in the same epitaxial growth run is a substantial challenge. Specifically, indium gallium nitride (InGaN) emission at long wavelengths in the red part of the visible spectrum has historically been inefficient and may remain so well into the commercial opportunity for such useful display devices such as augmented reality (AR) light sources.

Accordingly, there is a need for improved LED devices.

### SUMMARY

Embodiments of the disclosure are directed to LED devices and methods for manufacturing LED devices. In one or more embodiments, a light emitting diode (LED) comprise an epitaxial stack comprising a first active region and a second active region on an n-type layer, the first active region and the second active region separated by a tunnel junction; a p-type layer on the top surface of the second active region; and a red converting layer on a top surface of the p-contact layer.

Additional embodiments of the disclosure are directed to LED arrays. In one or more embodiments, an LED array of pixels comprises a first pixel comprising one or more of a blue emission or a green emission; and a second pixel adjacent the first pixel, the second pixel comprising a red emission and a red converting layer on a top surface of an epitaxial stack having a first active region and a second active region on an n-type layer, the first active region and the second active region separated by a tunnel junction; and a p-type layer on the top surface of the second active region.

Further embodiments of the disclosure are directed to methods of manufacturing LED die. In one or more embodiments, a method of manufacturing a light-emitting diode (LED) die comprises: epitaxially growing an epitaxial stack comprising a first active region and a second active region on an n-type layer, the first active region and the second active region separated by a tunnel junction; growing a p-type layer on the top surface of the second active region; and growing a red converting layer on a top surface of the p-contact layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a cross-section schematic of an epitaxy configuration according to one or more embodiments;

FIG. 2 illustrates a cross-section schematic of an epitaxy configuration according to one or more embodiments;

FIG. 3 illustrates a cross-section schematic of an epitaxy configuration according to one or more embodiments;

FIG. 4 illustrates a cross-section schematic an LED array according to one or more embodiments; and. 5 illustrates a process flow diagram for a method of an LED device according to one or more embodiments; and

FIG. 6 illustrates a block diagram of an example of a visualization system using the μLED array of one or more embodiments.

To facilitate understanding, identical reference numerals have been used, where possible, to designate identical elements that are common to the figures. The figures are not drawn to scale. For example, the heights and widths of the mesas are not drawn to scale.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate or on a substrate with one or more layers, films, features, or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN, and other alloys), metal alloys, and other conductive materials, depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed is also performed on an underlayer formed on the substrate, and the term “substrate surface” is intended to include such underlayer as the context indicates. Thus, for example, where a film/layer or partial film/layer has been deposited onto a 3 substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

Examples of different light illumination systems and/or light emitting diode (LED) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

Semiconductor light emitting devices or optical power emitting devices, such as devices that emit ultraviolet (UV) or infrared (IR) optical power, are among the most efficient light sources currently available. These devices may include light emitting diodes, resonant cavity light emitting diodes, vertical cavity laser diodes, edge emitting lasers, or the like (hereinafter referred to as “LEDs”). Due to their compact size and lower power requirements, for example, LEDs may be attractive candidates for many different applications. For example, they may be used as light sources (e.g., flashlights and camera flashes) for hand-held battery-powered devices, such as cameras and cell phones. They may also be used, for example, for automotive lighting, heads up display (HUD) lighting, horticultural lighting, street lighting, torch for video, general illumination (e.g., home, shop, office and studio lighting, theater/stage lighting and architectural lighting), augmented reality (AR) lighting, virtual reality (VR) lighting, as back lights for displays, and IR spectroscopy. A single LED may provide light that is less bright than an incandescent light source, and, therefore, multi-junction devices or arrays of LEDs (such as monolithic LED arrays, micro-LED arrays, etc.) may be used for applications where more brightness is desired or required.

The present disclosure generally relates to the manufacture of LEDs and arrays for augmented reality (AR) lighting.

Embodiments described herein describe LED devices and methods for forming LED devices. In particular, the present disclosure describes LED devices and methods to produce LED devices which are comprised of an epitaxial stack of two active regions separated by a tunnel junction grown successively. A red converting element is added selectively to pixels during device isolation/processing to create an array of pixels that can be controlled to be blue or green or a mix of the two, and other pixels that use the blue and/or green active regions to pump the red converting element to stimulate red light emission from this specific pixel area. In one or more alternative embodiments, during device processing to the topmost active region (green or blue) is selectively removed and replaced with a red converting material. In one or more embodiments, this permits a coplanar final structure.

In one or more embodiments, close packing of pixels allows high resolution. Though in theory, the resolution will not be as high resolution as a true three quantum well polychromatic pixel-based display, the resolution should easily surpass any Red Green Blue conversion scheme with the added benefit of high efficiency emission in blue and green facilitated by InGaN active regions.

The embodiments of the disclosure are described by way of the Figures, which illustrate devices and processes for forming devices in accordance with one or more embodiments of the disclosure. The processes shown are merely illustrative possible uses for the disclosed processes, and the skilled artisan will recognize that the disclosed processes are not limited to the illustrated applications.

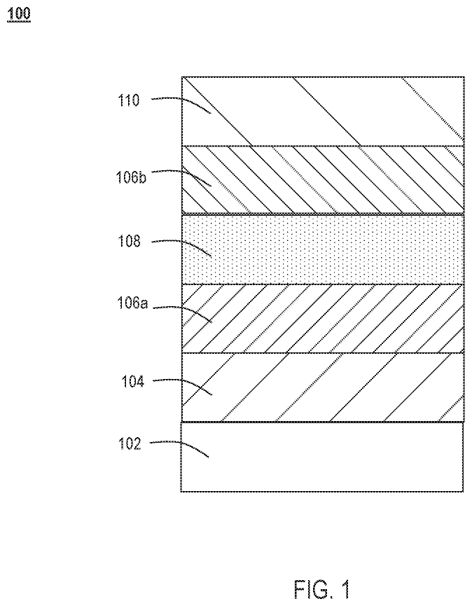

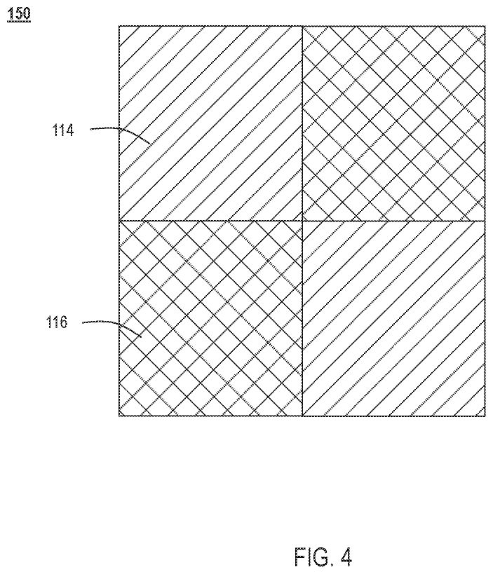

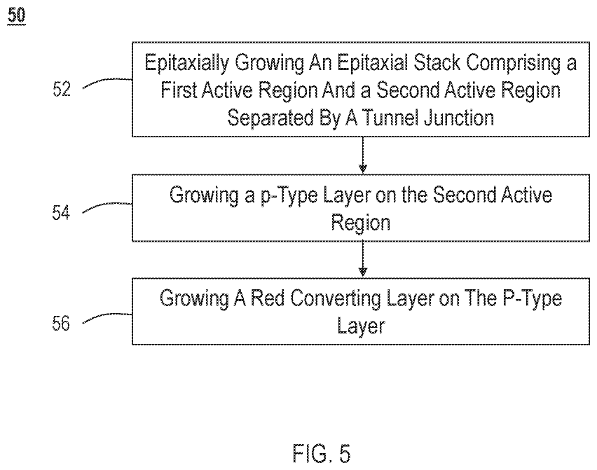

One or more embodiments of the disclosure are described with reference to the Figures. FIGS. 1-3 illustrate cross-sectional schematics of an epitaxy stack 100, according to one or more embodiments. An additional aspect of the disclosure pertains to and LED array, as illustrated in FIG. 4. FIG. 5 illustrates a process flow diagram for a method 50 on manufacturing an LED device according to one or more embodiments.

With reference to FIG. 5, in one or more embodiments, the method 50 begins at operation 52 by epitaxially growing an epitaxial stack comprising a first active region and a second active region separated by a tunnel junction on a substrate. At operation 54 a p-type layer is grown on the second active region. At operation 56, a red converting layer is grown on the p-type layer to emit a red light.

Referring to FIG. 1, a dual-active region LED wafer 100 is manufactured by forming a plurality of III-nitride layers on a substrate 102 including two light-emitting active regions. The light-emitting active regions include a first light-emitting active region 106a and a second light-emitting active region 106b. Any order of stacking the different active regions is within the scope of the disclosure.

According to certain specific embodiments, the LED wafer 100 comprises an n-type layer 104 formed on the substrate 102, a first light-emitting active region 106a grown on the n-type layer 104, a first tunnel junction 108 formed on the first active region 106a, a second light-emitting active region 106b grown on the tunnel junction 108, and a p-type layer 110 formed on the second light-emitting active region 106b.

In one or more embodiments, the first light-emitting active region 106a is a blue light emitting active region. In the embodiment shown, there is a tunnel junction 108 on the first light-emitting active region 106a. A tunnel junction is a structure that allows electrons to tunnel from the valence band of a p-type layer to the conduction band of an n-type layer in reverse bias. The location where a p-type layer and an n-type layer abut each other is called a p/n junction. When an electron tunnels, a hole is left behind in the p-type layer, such that carriers are generated in both regions. Accordingly, in an electronic device like a diode, where only a small leakage current flows in reverse bias, a large current can be carried in reverse bias across a tunnel junction. A tunnel junction comprises a particular alignment of the conduction and valence bands at the p/n tunnel junction. This can be achieved by using very high doping (e.g., in the p++/n++ junction). In addition, III-nitride materials have an inherent polarization that creates an electric field at heterointerfaces between different alloy compositions. In some circumstances, this polarization field can also be utilized to achieve band alignment for tunneling.

In one or more embodiments, the second light-emitting active region 106b is a green light emitting active region.

In one or more embodiments, a nucleation layer (not illustrated) and dislocation density control layers (not illustrated) may be grown on a suitable substrate 102, such as patterned or non-patterned sapphire. In one or more embodiments, the nucleation layer comprises a III-nitride material. In specific embodiments, the nucleation layer comprises gallium nitride (GaN) or aluminum nitride (AlN).

In one or more embodiments, the n-type layer 104 is grown on the substrate 102, the nucleation layer, and/or the dislocation density control layers. In one or more embodiments, the n-type layer 104 is formed on the substrate 102. The substrate 102 may be any substrate known to one of skill in the art which is configured for use in the formation of LED devices. In one or more embodiments, the substrate 102 comprises one or more of sapphire, silicon carbide, silicon (Si), quartz, magnesium oxide (MgO), zinc oxide (ZnO), spinel, and the like. In one or more embodiments, the substrate 102 is a transparent substrate. In specific embodiments, the substrate 102 comprises sapphire. In one or more embodiments, the substrate 102 is not patterned prior to formation of the LEDs. Thus, in some embodiments, the substrate is 102 not patterned and can be considered to be flat or substantially flat. In other embodiments, the substrate 102 is a patterned substrate.

In one or more embodiments, the n-type layer 104, may comprise any Group III-V semiconductors material, including binary, ternary, and quaternary alloys of gallium (Ga), aluminum (Al), indium (In), and nitrogen (N), also referred to as III-nitride materials. Thus, in some embodiments, the n-type layer 104, comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In a specific embodiment, the n-type layer 104, the second n-type layer 104b, and the third n-type layer 104c comprise gallium nitride (GaN). In one or more embodiments, the n-type layer 104 is doped with an n-type dopant, such as silicon (Si) or germanium (Ge). In one or more embodiments, the dopant concentration is in a range of from 1 e17 to 2e19 cm³. In one or more embodiments, the n-type layer 104 may have a thickness in the range of from 1 μm to 3 μm to ensure a wide process margin for a subsequent etching step used to contact this layer.

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD).

“Sputter deposition” as used herein refers to a physical vapor deposition (PVD) method of thin film deposition by sputtering. In sputter deposition, a material, e.g., a III-nitride, is ejected from a target that is a source onto a substrate. The technique is based on ion bombardment of a source material, the target. Ion bombardment results in a vapor due to a purely physical process, i.e., the sputtering of the target material.

As used according to some embodiments herein, “atomic layer deposition” (ALD) or “cyclical deposition” refers to a vapor phase technique used to deposit thin films on a substrate surface. The process of ALD involves the surface of a substrate, or a portion of substrate, being exposed to alternating precursors, i.e., two or more reactive compounds, to deposit a layer of material on the substrate surface. When the substrate is exposed to the alternating precursors, the precursors are introduced sequentially or simultaneously. The precursors are introduced into a reaction zone of a processing chamber, and the substrate, or portion of the substrate, is exposed separately to the precursors.

As used herein according to some embodiments, “chemical vapor deposition” refers to a process in which films of materials are deposited from the vapor phase by decomposition of chemicals on a substrate surface. In CVD, a substrate surface is exposed to precursors and/or co-reagents simultaneous or substantially simultaneously. A particular subset of CVD processes commonly used in LED manufacturing use metalorganic precursor chemical and are referred to as MOCVD or metalorganic vapor phase epitaxy (MOVPE). As used herein, “substantially simultaneously” refers to either co-flow or where there is overlap for a majority of exposures of the precursors.

As used herein according to some embodiments, “plasma enhanced atomic layer deposition (PEALD)” refers to a technique for depositing thin films on a substrate. In some examples of PEALD processes relative to thermal ALD processes, a material may be formed from the same chemical precursors, but at a higher deposition rate and a lower temperature. In a PEALD process, in general, a reactant gas and a reactant plasma are sequentially introduced into a process chamber having a substrate in the chamber. The first reactant gas is pulsed in the process chamber and is adsorbed onto the substrate surface. Thereafter, the reactant plasma is pulsed into the process chamber and reacts with the first reactant gas to form a deposition material, e.g., a thin film on a substrate. Similar to a thermal ALD process, a purge step may be conducted between the deliveries of each of the reactants.

As used herein according to one or more embodiments, “plasma enhanced chemical vapor deposition (PECVD)” refers to a technique for depositing thin films on a substrate. In a PECVD process, a source material, which is in gas or liquid phase, such as a gas-phase III-nitride material or a vapor of a liquid-phase III-nitride material that have been entrained in a carrier gas, is introduced into a PECVD chamber. A plasma-initiated gas is also introduced into the chamber. The creation of plasma in the chamber creates excited radicals. The excited radicals are chemically bound to the surface of a substrate positioned in the chamber, forming the desired film thereon.

In one or more embodiments, μLED array 100 is manufactured by placing the substrate 102 in a metalorganic vapor-phase epitaxy (MOVPE) reactor so that the μLED array layers are grown epitaxially.

In one or more embodiments, after the growth of the n-type layer 104, a first light-emitting active region 106a is grown. The first light-emitting active region 106a consists of multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for blue LEDs ranges from 3 to 15, the typical barrier thickness ranges from 5 nm to 25 nm, the well thickness ranges from 1 nm to 5 nm, and the well indium concentration ranges from 15% indium to 25% indium. In some embodiments, the active region may be doped with Si or Ge, while in other embodiments, the active region is undoped. After the first light-emitting active region 106a is grown, a tunnel junction 108 is grown on the first light-emitting active region 106a. In one or more embodiments, the tunnel junction 108 may be comprised of heavily doped p-GaN and n-GaN layers with doping concentrations in the range 10¹⁹-10²¹ cm⁻³ and layer thickness typically less than 50 nm. The tunnel junction 108 may also utilize thin InGaN or graded InGaN layers disposed between highly doped GaN layers.

In one or more embodiments, after the growth of the tunnel junction 108, a second light-emitting active region 106b is grown. The second light-emitting active region 106b consists of multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for green LEDs ranges from 4 to 12, the typical barrier, the typical barrier thickness ranges from 5 nm to 25 nm, the well thickness ranges from 1 nm to 5 nm, and the well indium concentration ranges from 15% indium to 25% indium. In some embodiments, the active region may be doped with Si or Ge, while in other embodiments, the active region is undoped. After the second light-emitting active region 106b is grown, a p-type layer 110 is grown on the second light-emitting active region 106b.

In one or more embodiments, p-type layer 110 comprises any Group III-V semiconductor material, including binary, ternary, and quaternary alloys of gallium (Ga), aluminum (Al), indium (In), and nitrogen (N), also referred to as III-nitride materials. Thus, in some embodiments, the p-type layer 110 comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In one or more embodiments, magnesium (Mg) is the acceptor dopant for the p-type layer 110.

In some embodiments, the p-type layer 110 comprises a sequence of doped p-type layers. In one or more embodiments, the p-type layer 110 comprises a gallium nitride (GaN) layer. The p-type layer 110 may be doped with any suitable p-type dopant known to the skilled artisan. In one or more embodiments, p-type layer 110 may be doped with magnesium (Mg). In one or more embodiments, the p-type layer 110 comprises a first magnesium doped p-type aluminum gallium nitride layer, a magnesium doped p-type gallium nitride layer, and a second magnesium doped p-type aluminum gallium nitride layer.

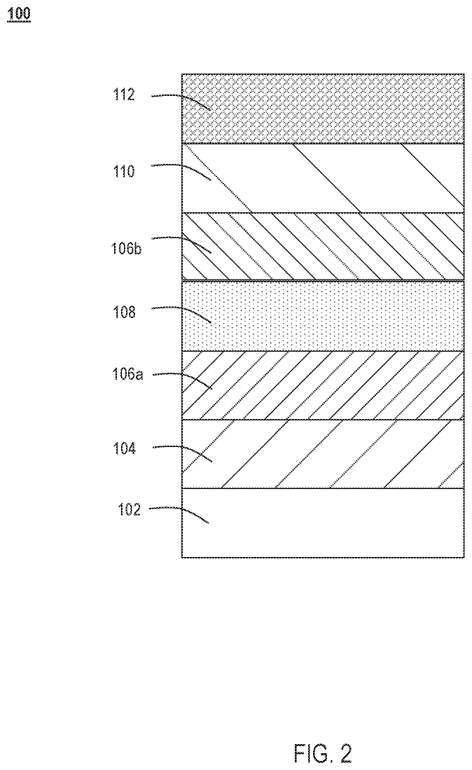

FIG. 2 illustrates a cross-section schematic of an LED device 100 after a red converting layer 112 is formed on a top surface of the p-type layer 110. In one or more embodiments, the red converting layer 112 advantageously replaces the function of a red indium gallium nitride (InGaN) emitting region in an LED. The red converting layer 112 is an efficient light conversion element, drawing upon a pump LED source to provide higher energy photos to the red converting layer 112, thus permitting red emission in this manner. In one or more embodiments, the red converting layer 112 comprises a patternable light conversion layer, including, but not limited to a quantum dot phosphor. In some embodiments, the red converting layer comprises a quantum dot converting layer. In other embodiments, the red converting layer comprises a phosphor layer.

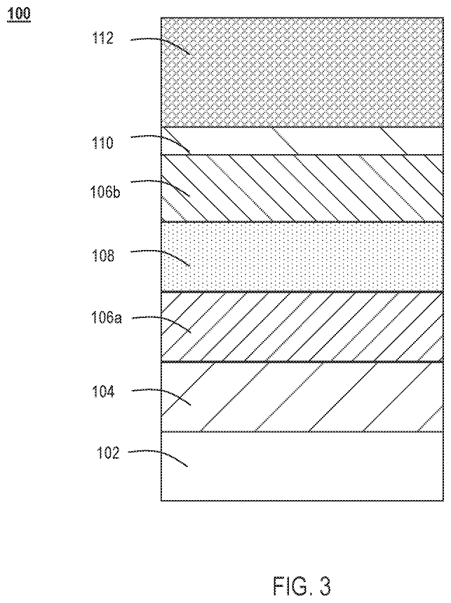

FIG. 3 illustrates a cross-section schematic of an LED device 100 after a red converting layer 112 is formed on a top surface of the p-type layer 110. In one or more embodiments, the second active region 106b may be selectively etched away and replaced with the red converting layer 112. In some embodiments, as illustrated, a portion, e.g., at least 30%, or at least 35%, or at least 40%, or at least 45%, or at least 50%, or at least 55%, or at least 60%, or at least 65%, or at least 70%, or least 75%, or at least 80% of the second active region 106b is selectively etched away and replaced with a red converting layer 112. In one or more embodiments, the red converting layer 112 advantageously replaces the function of a red indium gallium nitride (InGaN) emitting region in an LED. The red converting layer 112 is an efficient light conversion element, drawing upon a pump LED source to provide higher energy photos to the red converting layer 112, thus permitting red emission in this manner. In one or more embodiments, the red converting layer 112 comprises a patternable light conversion layer, including, but not limited to a quantum dot phosphor. In some embodiments, the red converting layer comprises a quantum dot converting layer. In other embodiments, the red converting layer comprises a phosphor layer.

FIG. 4 illustrates a cross-section schematic of an LED array 150 of pixels. The LED array 150 comprises a first pixel 114 comprising a blue or green emission and a second pixel 116 adjacent the first pixel 114, the second pixel 116 comprising a red emission. In one or more embodiments, the second pixel 116 comprises a red converting layer on a top surface of an epitaxial stack having a first active region and a second active region on an n-type layer, the first active region and the second active region separated by a tunnel junction, and a p-type layer on the top surface of the second active region.

In one or more embodiments, one or more of the first active region and the second active region emits green light. In other embodiments, one or more of the first active region and the second active region emits blue light. Thus, in one or more embodiments, the first pixel 114 emits one or more of green light or blue light.

In one or more embodiments, the n-type layer 104 is grown on a substrate, nucleation layer, and/or the dislocation density control layers. In one or more embodiments, the n-type layer 104 is formed on the substrate. The substrate may be any substrate known to one of skill in the art which is configured for use in the formation of LED devices. In one or more embodiments, the substrate comprises one or more of sapphire, silicon carbide, silicon (Si), quartz, magnesium oxide (MgO), zinc oxide (ZnO), spinel, and the like. In one or more embodiments, the substrate is a transparent substrate. In specific embodiments, the substrate comprises sapphire. In one or more embodiments, the substrate is not patterned prior to formation of the LEDs. Thus, in some embodiments, the substrate is not patterned and can be considered to be flat or substantially flat. In other embodiments, the substrate is a patterned substrate.

In one or more embodiments, the n-type layer 104, may comprise any Group III-V semiconductors material, including binary, ternary, and quaternary alloys of gallium (Ga), aluminum (Al), indium (In), and nitrogen (N), also referred to as III-nitride materials. Thus, in some embodiments, the n-type layer 104, comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In a specific embodiment, the n-type layer 104, the second n-type layer 104b, and the third n-type layer 104c comprise gallium nitride (GaN). In one or more embodiments, the n-type layer 104 is doped with an n-type dopant, such as silicon (Si) or germanium (Ge). In one or more embodiments, the n-type layer 104 may have a thickness in the range of from 1 μm to 3 μm to ensure a wide process margin for a subsequent etching step used to contact this layer.

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD).

In one or more embodiments, after the growth of the n-type layer 104, a first light-emitting active region 106a is grown. The first light-emitting active region 106a consists of multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for blue LEDs ranges from 3 to 15, the typical barrier thickness ranges from 5 nm to 25 nm, the well thickness ranges from 1 nm to 5 nm, and the well indium concentration ranges from 15% indium to 25% indium. In some embodiments, the active region may be doped with Si or Ge, while in other embodiments, the active region is undoped. After the first light-emitting active region 106a is grown, a tunnel junction 108 is grown on the first light-emitting active region 106a. In one or more embodiments, the tunnel junction 108 may be comprised of heavily doped p-GaN and n-GaN layers with doping concentrations in the range 10¹⁹-10²¹ cm⁻³ and layer thickness typically less than 50 nm. The tunnel junction 108 may also utilize thin InGaN or graded InGaN layers disposed between highly doped GaN layers.

In one or more embodiments, after the growth of the tunnel junction 108, a second light-emitting active region 106b is grown. The second light-emitting active region 106b consists of multiple quantum wells and may include electron blocking layer(s) grown after the quantum wells and strain-control layers grown before the quantum wells. The process of growing the strain-control layers may generate V-pit defects before the growth of the first quantum well. The number of quantum wells typically used for green LEDs ranges from 4 to 12, the typical barrier, the typical barrier thickness ranges from 5 nm to 25 nm, the well thickness ranges from 1 nm to 5 nm, and the well indium concentration ranges from 15% indium to 25% indium. In some embodiments, the active region may be doped with Si or Ge, while in other embodiments, the active region is undoped. After the second light-emitting active region 106b is grown, a p-type layer 110 is grown on the second light-emitting active region 106b.

In one or more embodiments, p-type layer 110 comprises any Group III-V semiconductor material, including binary, ternary, and quaternary alloys of gallium (Ga), aluminum (Al), indium (In), and nitrogen (N), also referred to as III-nitride materials. Thus, in some embodiments, the p-type layer 110 comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In one or more embodiments, magnesium (Mg) is the acceptor dopant for the p-type layer 110.

In one or more embodiments, one or more of the n-type layer 104, the first active region 106a, the second active region 106b, and the p-type layer 110 independently comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In specific embodiments, one or more of the n-type layer 104, the first active region 106a, the second active region 106b, and the p-type layer 110 independently comprise gallium nitride (GaN).

In some embodiments, the p-type layer 110 comprises a sequence of doped p-type layers. In one or more embodiments, the p-type layer 110 comprises a gallium nitride (GaN) layer. The p-type layer 110 may be doped with any suitable p-type dopant known to the skilled artisan. In one or more embodiments, p-type layer 110 may be doped with magnesium (Mg). In one or more embodiments, the p-type layer 110 comprises a first magnesium doped p-type aluminum gallium nitride layer, a magnesium doped p-type gallium nitride layer, and a second magnesium doped p-type aluminum gallium nitride layer.

In one or more embodiments, the red converting layer 112 advantageously replaces the function of a red indium gallium nitride (InGaN) emitting region in an LED. Thus, in one or more embodiments, the second pixel 116 emits a red light. The red converting layer 112 is an efficient light conversion element, drawing upon a pump LED source to provide higher energy photos to the red converting layer 112, thus permitting red emission in this manner. In one or more embodiments, the red converting layer 112 comprises a patternable light conversion layer, including, but not limited to a quantum dot phosphor. In some embodiments, the red converting layer comprises a quantum dot converting layer. In other embodiments, the red converting layer comprises a phosphor layer.

Visualization systems, such as virtual reality systems and augmented reality systems, are becoming increasingly more common in fields such as entertainment, education, medicine, and business.

In a virtual reality system, a display can present to a user a view of scene, such as a three-dimensional scene. The user can move within the scene, such as by repositioning the user's head or by walking. The virtual reality system can detect the user's movement and alter the view of the scene to account for the movement. For example, as a user rotates the user's head, the system can present views of the scene that vary in view directions to match the user's gaze. In this manner, the virtual reality system can simulate a user's presence in the three-dimensional scene. Further, a virtual reality system can receive tactile sensory input, such as from wearable position sensors, and can optionally provide tactile feedback to the user.

In an augmented reality system, the display can incorporate elements from the user's surroundings into the view of the scene. For example, the augmented reality system can add textual captions and/or visual elements to a view of the user's surroundings. For example, a retailer can use an augmented reality system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the augmented reality system can position a virtual chair in a room. The user can stand in the room on a front side of the virtual chair location to view the front side of the chair. The user can move in the room to an area behind the virtual chair location to view a back side of the chair. In this manner, the augmented reality system can add elements to a dynamic view of the user's surroundings.

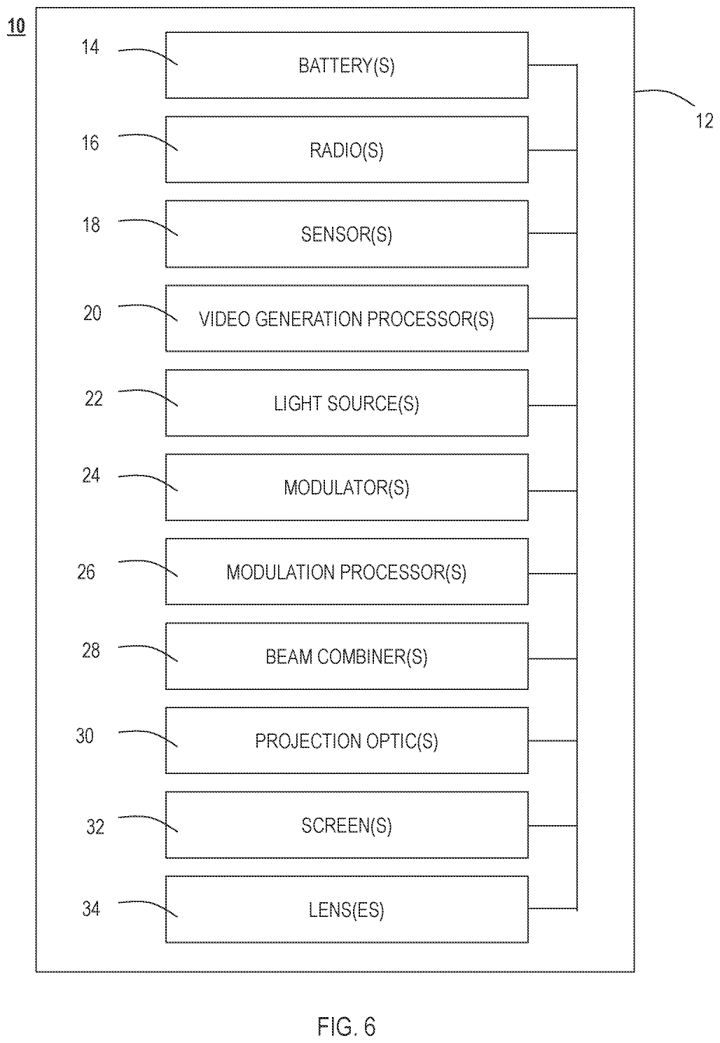

FIG. 6 shows a block diagram of an example of a visualization system 10 that utilizes the μLED array of one or more embodiments. The visualization system 10 can include a wearable housing 12, such as a headset or goggles. The housing 12 can mechanically support and house the elements detailed below. In some examples, one or more of the elements detailed below can be included in one or more additional housings that can be separate from the wearable housing 12 and couplable to the wearable housing 12 wirelessly and/or via a wired connection. For example, a separate housing can reduce the weight of wearable goggles, such as by including batteries, radios, and other elements. The housing 12 can include one or more batteries 14, which can electrically power any or all of the elements detailed below. The housing 12 can include circuitry that can electrically couple to an external power supply, such as a wall outlet, to recharge the batteries 14. The housing 12 can include one or more radios 16 to communicate wirelessly with a server or network via a suitable protocol, such as WiFi.

The visualization system 10 can include one or more sensors 18, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 18 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 18 can capture a real-time video image of the surroundings proximate a user.

The visualization system 10 can include one or more video generation processors 20. The one or more video generation processors 20 can receive from a server and/or a storage medium, scene data that represents a three-dimensional scene, such as a set of position coordinates for objects in the scene or a depth map of the scene. The one or more video generation processors 20 can receive one or more sensor signals from the one or more sensors 18. In response to the scene data, which represents the surroundings, and at least one sensor signal, which represents the location and/or orientation of the user with respect to the surroundings, the one or more video generation processors 20 can generate at least one video signal that corresponds to a view of the scene. In some examples, the one or more video generation processors 20 can generate two video signals, one for each eye of the user, which represent a view of the scene from a point of view of the left eye and the right eye of the user, respectively. In some examples, the one or more video generation processors 20 can generate more than two video signals and combine the video signals to provide one video signal for both eyes, two video signals for the two eyes, or other combinations.

The visualization system 10 can include one or more light sources 22 that can provide light for a display of the visualization system 10. Suitable light sources 22 can include a light-emitting diode, a monolithic light-emitting diode, a plurality of light-emitting diodes, an array of light-emitting diodes, an array of light-emitting diodes disposed on a common substrate, a segmented light-emitting diode that is disposed on a single substrate and has light-emitting diode elements that are individually addressable and controllable (and/or controllable in groups and/or subsets), an array of micro-light-emitting diodes (microLEDs), and others.

A light-emitting diode can be a white-light light-emitting diode. For example, a white-light light-emitting diode can emit excitation light, such as blue light or violet light. The white-light light-emitting diode can include one or more phosphors that can absorb some or all of the excitation light and can, in response, emit phosphor light, such as yellow light, which has a wavelength greater than a wavelength of the excitation light.

The one or more light sources 22 can include light-producing elements having different colors or wavelengths. For example, a light source can include a red light-emitting diode that can emit red light, a green light-emitting diode that can emit green light, and a blue light-emitting diode that can emit blue right. The red, green, and blue light combine in specified ratios to produce any suitable color that is visually perceptible in a visible portion of the electromagnetic spectrum.

In some embodiments, the light source comprises an LED array having a first pixel comprising one or more of a blue emission or a green emission and a second pixel adjacent the first pixel, the second pixel comprising a red emission, as described above in one or more embodiments.

The visualization system 10 can include one or more modulators 24. The modulators 24 can be implemented in one of at least two configurations.

In a first configuration, the modulators 24 can include circuitry that can modulate the light sources 22 directly. For example, the light sources 22 can include an array of light-emitting diodes, and the modulators 24 can directly modulate the electrical power, electrical voltage, and/or electrical current directed to each light-emitting diode in the array to form modulated light. The modulation can be performed in an analog manner and/or a digital manner. In some examples, the light sources 22 can include an array of red light-emitting diodes, an array of green light-emitting diodes, and an array of blue light-emitting diodes, and the modulators 24 can directly modulate the red light-emitting diodes, the green light-emitting diodes, and the blue light-emitting diodes to form the modulated light to produce a specified image.

In a second configuration, the modulators 24 can include a modulation panel, such as a liquid crystal panel. The light sources 22 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 24 can include multiple modulation panels that can modulate different colors of light. For example, the modulators 24 can include a red modulation panel that can attenuate red light from a red-light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 24 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 10 can include one or more modulation processors 26, which can receive a video signal, such as from the one or more video generation processors 20, and, in response, can produce an electrical modulation signal. For configurations in which the modulators 24 directly modulate the light sources 22, the electrical modulation signal can drive the light sources 24. For configurations in which the modulators 24 include a modulation panel, the electrical modulation signal can drive the modulation panel.

The visualization system 10 can include one or more beam combiners 28 (also known as beam splitters 28), which can combine light beams of different colors to form a single multi-color beam. For configurations in which the light sources 22 can include multiple light-emitting diodes of different colors, the visualization system 10 can include one or more wavelength-sensitive (e.g., dichroic) beam splitters 28 that can combine the light of different colors to form a single multi-color beam.

The visualization system 10 can direct the modulated light toward the eyes of the viewer in one of at least two configurations. In a first configuration, the visualization system 10 can function as a projector, and can include suitable projection optics 30 that can project the modulated light onto one or more screens 32. The screens 32 can be located a suitable distance from an eye of the user. The visualization system 10 can optionally include one or more lenses 34 that can locate a virtual image of a screen 32 at a suitable distance from the eye, such as a close-focus distance, such as 500 mm, 750 mm, or another suitable distance. In some examples, the visualization system 10 can include a single screen 32, such that the modulated light can be directed toward both eyes of the user. In some examples, the visualization system 10 can include two screens 32, such that the modulated light from each screen 32 can be directed toward a respective eye of the user. In some examples, the visualization system 10 can include more than two screens 32. In a second configuration, the visualization system 10 can direct the modulated light directly into one or both eyes of a viewer. For example, the projection optics 30 can form an image on a retina of an eye of the user, or an image on each retina of the two eyes of the user.

For some configurations of augmented reality systems, the visualization system 10 can include an at least partially transparent display, such that a user can view the user's surroundings through the display. For such configurations, the augmented reality system can produce modulated light that corresponds to the augmentation of the surroundings, rather than the surroundings itself. For example, in the example of a retailer showing a chair, the augmented reality system can direct modulated light, corresponding to the chair but not the rest of the room, toward a screen or toward an eye of a user.

### EMBODIMENTS

Various embodiments are listed below. It will be understood that the embodiments listed below may be combined with all aspects and other embodiments in accordance with the scope of the invention.

Embodiment (a). A light emitting diode (LED) device comprising: an epitaxial stack comprising a first active region and a second active region on an n-type layer, the first active region and the second active region separated by a tunnel junction; a p-type layer on the top surface of the second active region; and a red converting layer on a top surface of the p-contact layer.

Embodiment (b) The LED die of embodiment (a), wherein the red converting layer comprises a quantum dot converting layer.

Embodiment (c). The LED die of embodiment (a), wherein the red converting layer comprises a phosphor layer.

Embodiment (d). The LED die of embodiments (a) through (c), wherein one or more of the first active region and the second region emits green light.

Embodiment (e). The LED die of embodiments (a) through (d), wherein one or more of the first active region and the second region emits blue light.

Embodiment (f). LED die of embodiments (a) through (e), wherein one or more of the n-type layer, the first active region, the second active region, and the p-type layer independently comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

Embodiment (g). The LED die of embodiments (a) through (f), wherein the n-type layer, comprises gallium nitride (GaN).

Embodiment (h). The LED die of embodiments (a) through (g), wherein the LED forms a part of an RGB display.

Embodiment (i). The LED die embodiments (a) through (h), wherein the LED is a microLED.

Embodiment (j). An LED array of pixels comprising: a first pixel comprising one or more of a blue emission or a green emission; and a second pixel adjacent the first pixel, the second pixel comprising a red emission and a red converting layer on a top surface of an epitaxial stack having a first active region and a second active region on an n-type layer, the first active region and the second active region separated by a tunnel junction; and a p-type layer on the top surface of the second active region.

Embodiment (k). The LED array of embodiment (j), wherein one or more of the first active region and the second active region emits green light.

Embodiment (l). The LED array of embodiment (j) through (k), wherein one or more of the first active region and the second region emits blue light.

Embodiment (m). The LED array of embodiment (j) through (l), wherein one or more of the n-type layer, the first active region, the second active region, and the p-type layer independently comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

Embodiment (n). The LED array of embodiment (j) through (m), wherein the n-type layer, comprises gallium nitride (GaN).

Embodiment (o). The LED array of embodiment (j) through (n), wherein the red converting layer comprises a quantum dot converting layer.

Embodiment (p). The LED array of embodiment (j) through (o), wherein the red converting layer comprises a phosphor layer.

Embodiment (q). A method of manufacturing a light-emitting diode (LED) die, the method comprising: epitaxially growing an epitaxial stack comprising a first active region and a second active region on an n-type layer, the first active region and the second active region separated by a tunnel junction; growing a p-type layer on the top surface of the second active region; and growing a red converting layer on a top surface of the p-contact layer

Embodiment (r). The method of embodiment (q), further comprising selectively removing a portion of the second active region prior to growing the red converting layer.

Embodiment(s). The method of embodiment (q) through (r), wherein the red converting layer comprises a quantum dot converting layer.

Embodiment (t). The method of embodiment (q) through(s), wherein the red converting layer comprises a phosphor layer.

Embodiment (u). The method of embodiment (q) through (t), wherein one or more of the first active region and the second region emits green light.

Embodiment (v). The method of embodiment (q) through (u), wherein one or more of the first active region and the second region emits blue light.

Embodiment (w). A visualization system, comprising: a battery; a radio; a sensor; a video generation process; a light source comprising an LED array having a first pixel comprising one or more of a blue emission or a green emission and a second pixel adjacent the first pixel, the second pixel comprising a red emission; a modulator; a modulation processor; a beam combiner; a projection optic; a screen; and a lens.

Embodiment (x). The visualization system of embodiment (w), wherein: the first pixel comprises a blue emission; and the second pixel comprises a red converting layer on a top surface of an epitaxial stack having a first active region and a second active region on an type layer, the first active region and the second active region separated by a tunnel junction; and a p-type layer on the top surface of the second active region.

Embodiment (y). The visualization system of embodiment (w) through (x), wherein: the first pixel comprises a green emission; and the second pixel comprises a red converting layer on a top surface of an epitaxial stack having a first active region and a second active region on an n-type layer, the first active region and the second active region separated by a tunnel junction; and a p-type layer on the top surface of the second active region.

Embodiment (z). The visualization system of embodiment (w) through (y), wherein one or more of the first active region and the second active region emits green light.

Embodiment (aa). The visualization system of embodiment (w) through (z), wherein one or more of the first active region and the second region emits blue light.

Embodiment (bb). The visualization system of embodiment (w) through (aa), wherein one or more of the first active region and the second active region emits green light.

Embodiment (cc). The visualization system of embodiment (w) through (bb), wherein one or more of the first active region and the second region emits blue light.

Embodiment (dd). The visualization system of embodiment (w) through (cc), wherein one or more of the n-type layer, the first active region, the second active region, and the p-type layer independently comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

Embodiment (ee). The visualization system of embodiment (w) through (dd), wherein one or more of the n-type layer, the first active region, the second active region, and the p-type layer independently comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

Embodiment (ff). The visualization system of embodiment (w) through (ee), wherein the n-type layer, comprises gallium nitride (GaN).

Embodiment (gg). The visualization system of embodiment (w) through (ff), wherein the n-type layer, comprises gallium nitride (GaN).

Embodiment (hh). The visualization system of embodiment (w) through (gg), wherein the red converting layer comprises a quantum dot converting layer.

Embodiment (ii). The visualization system of embodiment (w) through (hh), wherein the red converting layer comprises a phosphor layer.

Embodiment (jj). The visualization system of embodiment (w) through (ii), wherein the red converting layer comprises a quantum dot converting layer.

Embodiment (kk). The visualization system of embodiment (w) through (jj), wherein the red converting layer comprises a phosphor layer.

Embodiment (ll). The visualization system of embodiment (w) through (kk), wherein the visualization system is an augmented reality system.

Embodiment (mm). The visualization system of embodiment (w) through (ll), wherein the LED array is a μLED array.

Embodiment (nn). The visualization system of embodiment (w) through (mm), wherein the video generation processor generates two video signals, one for each eye of a user.

Embodiment (oo). The visualization system of embodiment (w) through (nn), wherein the modulator comprises circuitry to modulate the light source directly.

Embodiment (pp). The visualization system of embodiment (w) through (oo), wherein the modulator comprises a modulation panel.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to the terms first, second, third, etc. may be used herein to describe various elements, and these elements should not be limited by these terms. These terms may be used to distinguish one element from another.

Reference throughout this specification to a layer, region, or substrate as being “on” or extending “onto” another element, means that it may be directly on or extend directly onto the other element or intervening elements may also be present. When an element is referred to as being “directly on” or extending “directly onto” another element, there may be no intervening elements present. Furthermore, when an element is referred to as being “connected” or “coupled” to another element, it may be directly connected or coupled to the other element and/or connected or coupled to the other element via one or more intervening elements. When an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1.-20. (canceled)

21. A light-emitting diode (LED) comprising:
an epitaxial stack comprising a first active region and a second active region on an n-type layer, the first active region and the second active region separated by a tunnel junction;
a p-type layer on the top surface of the second active region; and
a red converting layer on a top surface of the p-contact layer.

22. The LED die of claim 21, wherein the red converting layer comprises one or more of a quantum dot converting layer and a phosphor layer.

23. The LED die of claim 21, wherein one or more of the first active region and the second region emits green light.

24. The LED die of claim 21, wherein one or more of the first active region and the second region emits blue light.

25. The LED die of claim 21, wherein one or more of the n-type layer, the first active region, the second active region, and the p-type layer independently comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

26. The LED die of claim 25, wherein one or more of the n-type layer, the first active region, the second active region, and the p-type layer independently comprises gallium nitride (GaN).

27. The LED die of claim 21, wherein the LED forms a part of an RGB display.

28. The LED die of claim 27, wherein the LED is a microLED.

29. An LED array of pixels comprising:
a first pixel comprising one or more of a blue emission or a green emission; and
a second pixel adjacent the first pixel, the second pixel comprising a red emission and a red converting layer on a top surface of an epitaxial stack having a first active region and a second active region on an n-type layer, the first active region and the second active region separated by a tunnel junction; and a p-type layer on the top surface of the second active region.

30. The LED array of claim 29, wherein one or more of the first active region and the second active region emits green light.

31. The LED array of claim 29, wherein one or more of the first active region and the second region emits blue light.

32. The LED array of claim 29, wherein one or more of the n-type layer, the first active region, the second active region, and the p-type layer independently comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

33. The LED array of claim 29, wherein one or more of the n-type layer, the first active region, the second active region, and the p-type layer independently comprises gallium nitride (GaN).

34. The LED array of claim 29, wherein the red converting layer comprises one or more of a quantum dot converting layer or a phosphor layer.

35. A method of manufacturing a light-emitting diode (LED) die, the method comprising:
epitaxially growing an epitaxial stack comprising a first active region and a second active region on an n-type layer, the first active region and the second active region separated by a tunnel junction;
growing a p-type layer on the top surface of the second active region; and
growing a red converting layer on a top surface of the p-contact layer.

36. The method of claim 35, further comprising selectively removing a portion of the second active region prior to growing the red converting layer.

37. The method of claim 35, wherein the red converting layer comprises one or more of a quantum dot converting layer or a phosphor layer.

38. The method of claim 35, wherein one or more of the first active region and the second region emits green light.

39. The method of claim 35, wherein one or more of the first active region and the second region emits blue light.

40. A visualization system, comprising:
a battery;
a radio;
a sensor;
a video generation process;
a light source comprising the LED array of claim 9;
a modulator;
a modulation processor;
a beam combiner;
a projection optic;
a screen; and
a lens.
